(19) United States
(12) Patent Application Publication
(10) Pub. No.: US 2009/0002944 A1
(43) Pub. Date: Jan. 1, 2009

(54) Ventilating Exhaust Fan Housing

(76) Inventor: Max Su, Taichung (TW)

Correspondence Address: HDSL, P.O. BOX 220746, CHANTILLY, VA, 20153-0746, US

(21) Appl. No.: 11/772,236

(22) Filed: Jul. 1, 2007

(51) Int. Cl. H05K 7/20

(52) U.S. Cl. 361/695; 361/724; 454/254

(57) ABSTRACT

A ventilating exhaust fan housing substantially is a two-piece construction formed from a first structural member and a second structural member. The housing has six sides surrounding and defining an interior space of the housing. The six sides include five sides defined by walls of the housing, and a sixth open side acting as a fluid inlet. The first structural member substantially defines the walls of four sides of the housing, and one of the walls of the four sides defines a fluid outlet penetrating therethrough. The second structural member substantially defines the wall of fifth side of the housing. Therefore, the first structural member and the second structural member cooperatively form a compact ventilating exhaust fan housing.

### BACKGROUND

1. Technical Field

The present invention relates generally to ventilating exhaust fan housings, and more particularly, to a ventilating exhaust fan housing being compact and thus could significantly reduce manufacturing waste.

2. Description of the Related Art

Ventilating exhaust fans have fan housings most of which are made from metal sheets. The conventional fan housings generally have complex unfolded structures so as to meet the needs of practical structures as required or combinations with external constructions such as ceilings. However, in the manufacturing processes of the complex unfolded structures, it is inevitably to produce many waste materials cut from raw metal sheets, which results in significant waste of resources and cost and thus the manufacturing cost of the manufacturers is increased as a result. Accordingly, how to fully make use of the raw metal sheets and reduce the waste materials have been became the focus of attention for the manufacturers.

### BRIEF SUMMARY

The present invention is to provide a compact ventilating exhaust fan housing.

A ventilating exhaust fan housing, in accordance with a preferred embodiment, is provided. The ventilating exhaust fan housing substantially is a two-piece construction formed from a first structural member and a second structural member. The housing has six sides surrounding and defining an interior space of the housing. The six sides include five sides defined by walls of the housing, and a sixth open side acting as a fluid inlet. The first structural member substantially defines the walls of four sides of the housing, and one of the walls of the four sides defines a fluid outlet penetrating therethrough. The second structural member substantially defines the wall of fifth side of the housing. The first structural member and the second structural member cooperatively form a compact ventilating exhaust fan housing.

Compared with conventional fan housings, the present ventilating exhaust fan housing makes use of a first structural member to define the walls of the four sides of the housing and a second structural member to define the wall of the fifth side of the ventilating exhaust fan housing, the first and the second structural members are compact, edges thereof are substantially linear and almost without any protruding portions. As a result, the waste materials could be reduced in the manufacturing processes of the first and the second structural members. Especially for mass production of the ventilating exhaust fan housing, the waste materials produced in the manufacturing process of the ventilating exhaust fan housing can be significantly saved and thus the manufacturing cost can be reduced consequently.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic, perspective view of a ventilating exhaust fan housing, in accordance with a first preferred embodiment.

FIG. 2 is a schematic, exploded view of the ventilating exhaust fan housing of FIG. 1, showing a first structural member and a second structural member.

FIG. 3 is a schematic, unfolded view of the first structural member of FIG. 2.

FIG. 4 is a schematic, unfolded view of the second structural member of FIG. 2.

FIG. 5 is a schematic, perspective view of a finally finished ventilating exhaust fan housing, in accordance with the first preferred embodiment.

FIG. 6 is a schematic, isometric view of a ventilating exhaust fan housing, in accordance with a second preferred embodiment.

FIG. 7 is a schematic, exploded view of the ventilating exhaust fan housing of FIG. 6, showing a first structural member and a second structural member.

FIG. 8 is a schematic, unfolded view of the first structural member of FIG. 7.

FIG. 9 is a schematic, side view of the ventilating exhaust fan housing of FIG. 6.

FIG. 10 is a schematic, side view of the ventilating exhaust fan housing of FIG. 1.

### DETAILED DESCRIPTION

The present invention utilizes a first structural member and a second structural member which are compact and edges thereof are substantially linear, cooperatively to define five walls of a ventilating exhaust fan housing, and thus the amount of waste materials are significantly reduced.

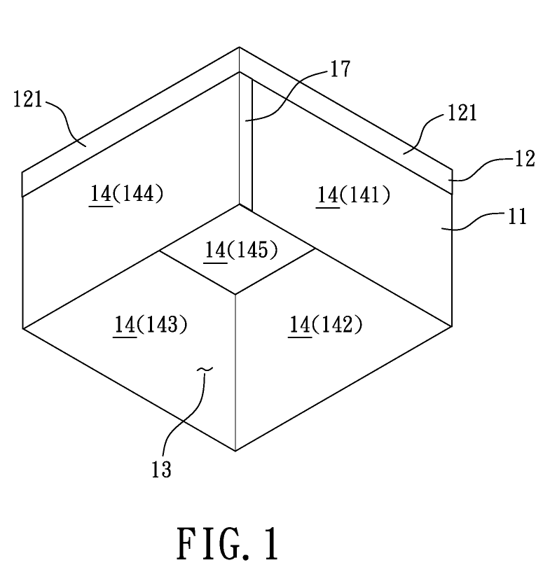

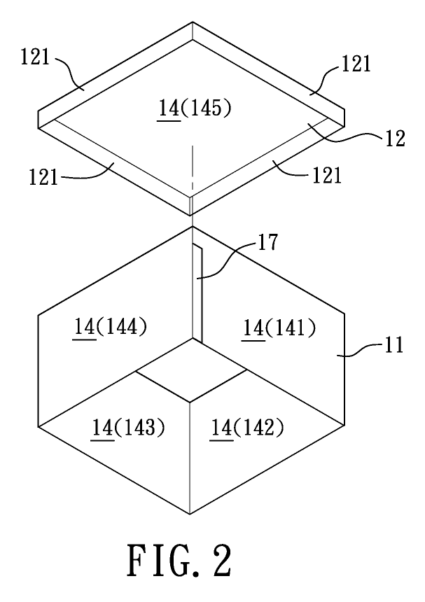

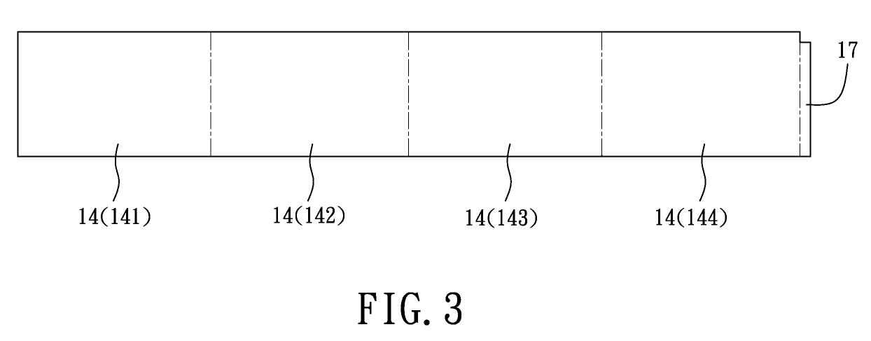

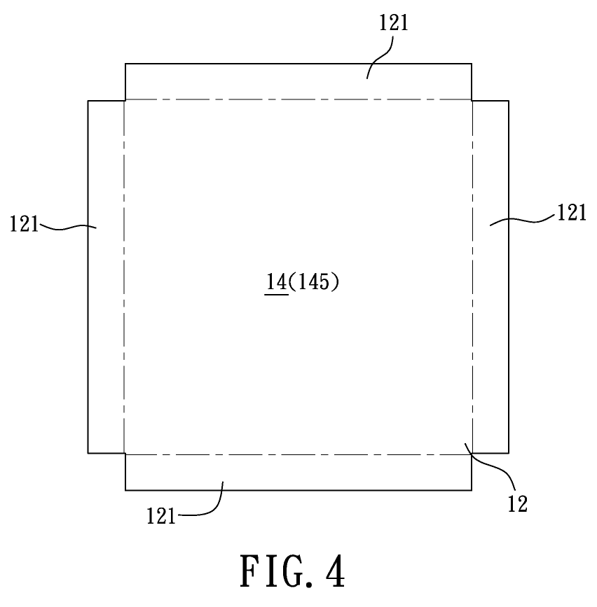

Referring to FIGS. 1 through 5, and FIG. 10, a ventilating exhaust fan housing, in accordance with a first preferred embodiment, is provided. The ventilating exhaust fan housing essentially is a two-piece construction formed from a first structural member 11 and a second structural member 12. The ventilating exhaust fan housing has six sides surrounding and defining an interior space 13 thereof. The six sides includes five sides defined by walls 14, and a sixth open side 15 acting as a fluid inlet (as shown in FIG. 10).

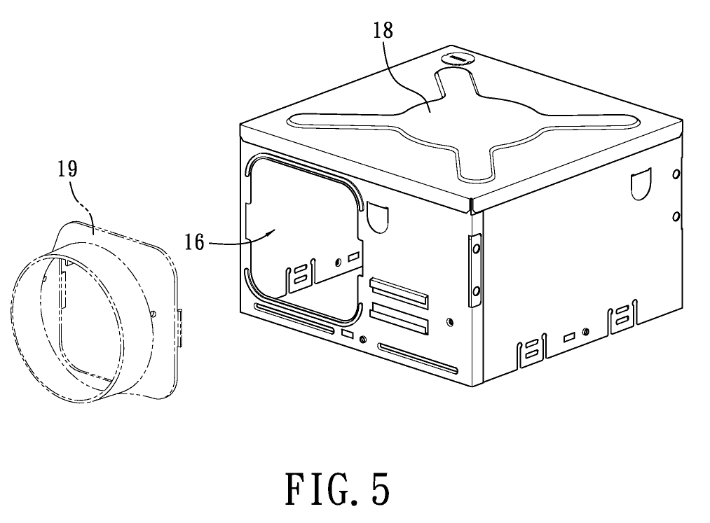

The first structural member 11 suitably is a single integral sheet of material. The first structural member 11 defines the walls 14 of four sides of the ventilating exhaust fan housing, i.e., first wall 14(141), second wall 14(142), third wall 14(143) and fourth wall 14(144), as illustrated in FIGS. 1 through 3, and one of the four walls 14 defines a fluid outlet 16 penetrating therethrough (as shown in FIG. 5). Generally, the four walls 14 cooperatively encircle the interior space 13 of the ventilating exhaust fan housing. Furthermore, the first structural member 11 includes a mounting flange 17 arranged at the rear of the fourth wall 14(144). The fourth wall 14(144) is joined to the first wall 14(141) via the mounting flange 17 attached to the first wall 14(141).

The second structural member 12 suitably is a single integral sheet of material. The second structural member 12 defines the wall 14(145) of fifth side of the ventilating exhaust fan housing. Furthermore, the second structural member 12 includes peripheral edge flanges 121 arranged around the wall 14(145). The peripheral edge flanges 121 are bent at a same direction substantially perpendicular to the wall 14(145). The wall 14(145) is joined to the walls 14 of the four sides defined by the first structural member 11 via the four peripheral edge flanges 121 respectively attached to a corresponding one edge of the walls 14 of the four sides.

Referring to FIGS. 1 through 5, in the illustrated embodiment, the mounting flange 17 of the first structural member 11 has a height (i.e., generally a length) lower than that of the four walls 14 thereof and is attached outside of the first wall 14(141). When the wall 14(145) of the fifth side defined by the second structural member 12 is joined to the first structural member 11, the four peripheral edge flanges 121 are respectively attached to a corresponding one edge of the walls 14 of the four sides defined by the first structural member 11, and one of the peripheral edge flanges 121 is substantially supported on a top portion of the mounting flange 17. Therefore, the ventilating exhaust fan housing, in accordance with the first preferred embodiment, is formed.

A ventilating exhaust fan housing, in accordance with a second preferred embodiment, is similar to the ventilating exhaust fan housing in accordance with the first preferred embodiment, and thus the components thereof similar to those in the aforementioned first preferred embodiment will be omitted to describe herein.

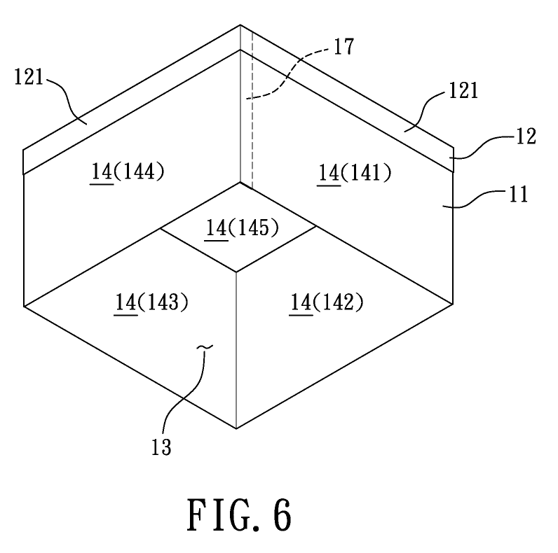

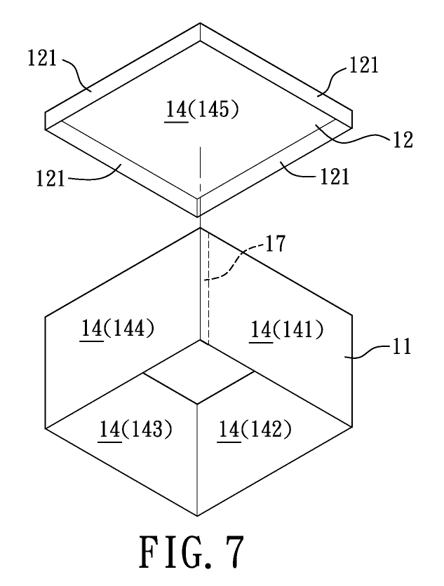

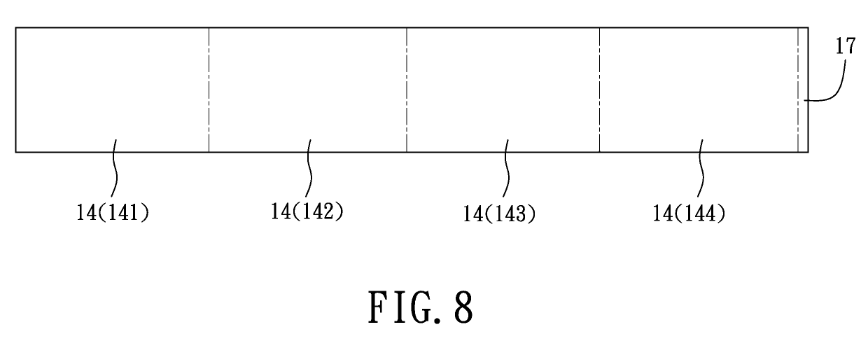

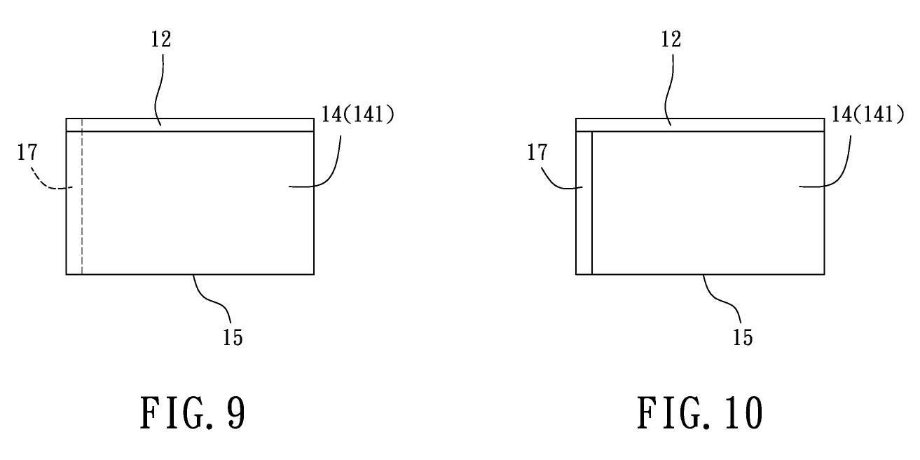

Referring to FIGS. 6 through 9, in the second preferred embodiment, the mounting flange 17 of the first structural member 11 has a height is approximately equal to that of the four walls 14 defined by the first structural member 11, and is attached to inside of the first wall 14(141). When the wall 14(145) of the fifth side defined by the second structural member 12 is joined to the first structural member 11, the four peripheral edge flanges 121 of the second structural member 12 are respectively attached to a corresponding one edge of the walls 14 of the four sides defined by the first structural member 11 and thereby the ventilating exhaust fan housing, in accordance with the second preferred embodiment, is formed.

It is understood to the skilled person in the art that the aforementioned heights (or generally lengths) of the mounting flange 17 of the first structural member 11 are intended to illustrate rather than limit the invention. Because the mounting flange 17 mainly is used to join the first wall 14(141) and the fourth wall 14(144) together, and thus various modifications made to the mounting flange 17 by those skilled in the art without departing from the true spirit of the invention are intended to be included in the scope of this invention.

It is also understood to the skilled person in the art that the present invention mainly is to provide a basic structure of a ventilating exhaust fan housing, and thus other structures formed in a subsequent machining process or conventional structures, such as a fluid outlet 16, a strengthen member 19, an external outlet fitting 19 and so on (as shown in FIG. 5), are omitted to be given a detailed description. FIG. 5 shows a finally finished ventilating exhaust fan housing in accordance with a preferred embodiment for the purpose of illustration.

In summary, as described in the illustrative embodiments, the present invention utilizes a first structural member 11 and a second structural member 12 cooperatively to define walls of five sides of a ventilating exhaust fan housing, the first structural member 11 and the second structural member 12 are compact and easily to be joined together. Consequently, the manufacturing cost of a ventilating exhaust fan can be greatly saved and the amount of waste materials can be significantly reduced.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A ventilating exhaust fan housing substantially being a two-piece construction, comprising:
six sides surrounding and defining an interior space of the housing, the six sides including five sides defined by walls of the housing and a sixth open side acting as a fluid inlet;
a first structural member substantially being a single integral sheet of material and defining the walls of four sides of the housing; and
a second structural member substantially being a single integral sheet of material and defining the wall of fifth side of the housing.

2. The ventilating exhaust fan housing according to claim 1, wherein the second structural member comprises the wall of the fifth side and peripheral edge flanges arranged around the wall of the fifth side, the peripheral edge flanges are bent at a same direction substantially perpendicular to the wall of the fifth side, the second structural member is joined with edges of the walls of the four sides defined by the first structural member via the peripheral edge flanges.

3. The ventilating exhaust fan housing according to claim 1, wherein the first structural member comprises the walls of the four sides and a mounting flange arranged at the rear of a fourth wall of the four sides, the mounting flange is attached to a first wall of the four sides.

4. The ventilating exhaust fan housing according to claim 3, wherein the mounting flange is attached to an outside edge of the first wall.

5. The ventilating exhaust fan housing according to claim 3, wherein the mounting flange is attached to an inside edge of the first wall.

6. The ventilating exhaust fan housing according to claim 1, wherein the first structural member comprises the walls of the four sides and a mounting flange arranged at the rear of a fourth wall of the four sides, the mounting flange is attached to an outside edge of a first wall of the four sides and has a height lower than that of the walls of the four sides; the second structural member comprises the wall of the fifth side and peripheral edge flanges arranged around the wall of the fifth side, the peripheral edge flanges are bent at a same direction substantially perpendicular to the wall of the fifth side, the second structural member is joined with edges of the walls of the four sides defined by the first structural member via the peripheral edge flanges and one of the peripheral edge flanges is supported on a top portion of the mounting flange.

7. A ventilating exhaust fan housing, comprising:
six sides surrounding and defining an interior space of the housing, the six sides including five sides defined by walls of the housing and a sixth open side acting as a fluid inlet;
a first structural member and a second structural member joined with each other and substantially cooperatively defining the walls of the five sides of the housing; and
wherein a first structural member being a single sheet of material and encircling the interior space of the housing, the second structural member substantially being a single sheet of material and arranged opposite to sixth open side.
